(19) United States
(12) Patent Application Publication
(10) Pub. No.: US 2024/0334783 A1
(43) Pub. Date: Oct. 3, 2024

(54) DISPLAY DEVICE

(71) Applicant: Samsung Display Co., LTD., Yongin-si (KR)

(72) Inventors: SEUNGJIN LIM, Yongin-si (KR); JONGSUK LEE, Yongin-si (KR); JUNGMIN PARK, Yongin-si (KR); JIHOON SONG, Yongin-si (KR); JONGSOO LEE, Yongin-si (KR)

(21) Appl. No.: 18/406,099

(22) Filed: Jan. 6, 2024

(30) Foreign Application Priority Data
Mar. 30, 2023 (KR) 10-2023-0042304

(51) Int. Cl. H10K 59/80

(52) U.S. Cl. CPC H10K 59/873; H10K 2102/311

(57) ABSTRACT

A display device includes a display panel including a flat portion and a bending portion bent from the flat portion and a protective film disposed under the display panel to overlap the flat and bending portions. The bending portion includes a first bending portion extending from a first side of the flat portion and bent with a first curvature about a first bending axis and a second bending portion extending from a second side of the flat portion and bent with a second curvature about a second bending axis. The protective film includes first patterns extending in a direction parallel to the first bending axis to overlap the first bending portion and second patterns extending in a direction parallel to the second bending axis to overlap the second bending portion. A number of the first patterns and a number of the second patterns differs from each other.

This application claims priority to Korean Patent Application No. 10-2023-0042304, filed on Mar. 30, 2023, and all the benefits accruing therefrom under 35 U.S.C. § 119, the content of which in its entirety is herein incorporated by reference.

### BACKGROUND

### 1. Field

Embodiments of the disclosure described herein relate to a display device, and more particularly, relate to a display device having improved reliability.

### 2. Description of the Related Art

Multimedia devices, such as a television, a mobile phone, a tablet computer, a car navigation unit, a game machine, and the like, may include a display device for displaying an image. With the development of display device technology, various types of display device are being developed. For example, a display device may display an image through a display surface including a curved surface.

The display device may be manufactured by laminating a window and a display module including a display panel. The display device including a curved surface may be formed by attaching the display module to the window having a curved surface.

### SUMMARY

In a lamination process for attaching a display module to a window having a curved surface, the display module may be wrinkled when the display module is attached to a curved portion of the window.

Embodiments of the disclosure provide a display device for preventing a display panel from being wrinkled or damaged in a process in which the display panel is attached to a window including a bending region.

According to an embodiment, a display device includes a display panel including a flat portion and a bending portion bent from the flat portion and a protective film disposed under the display panel to overlap the flat portion and the bending portion. In such an embodiment, the bending portion includes a first bending portion which extends from a first side of the flat portion and is bent with a first curvature about a first bending axis and a second bending portion which extends from a second side of the flat portion and is bent with a second curvature different from the first curvature about a second bending axis. In such an embodiment, the protective film includes a plurality of first patterns which extends in a direction parallel to the first bending axis in a first region to overlap the first bending portion and a plurality of second patterns which extends in a direction parallel to the second bending axis in a second region to overlap the second bending portion. In such an embodiment, a number of the first patterns and a number of the second patterns differs from each other.

In an embodiment, the first curvature may be greater than the second curvature.

In an embodiment, the first bending axis and the second bending axis may cross each other at a right angle, the first patterns may be arranged in the direction parallel to the second bending axis, and the second patterns may be arranged in the direction parallel to the first bending axis.

In an embodiment, the number of the first patterns may be greater than the number of the second patterns.

In an embodiment, the protective film may include a bending region defined to overlap the first bending portion and the second bending portion and a flat region defined to overlap the flat portion.

In an embodiment, the bending region may include a patterned region in which the first patterns and the second patterns are defined and an unpatterned region in which the first patterns and the second patterns are not defined.

In an embodiment, the unpatterned region may include a first unpatterned region disposed at one side of the patterned region and located between the patterned region and the flat region and a second unpatterned region disposed at an opposite side of the patterned region which is opposite to the one side of the patterned region.

In an embodiment, the second unpatterned region may have a width in a range from about 20% to about 30% of a width of the bending region.

In an embodiment, the bending portion may further include a corner portion connected between the first bending portion and the second bending portion.

In an embodiment, the first patterns and the second patterns may not overlap the corner portion.

In an embodiment, the display device may further include a window disposed on the display panel to overlap the flat portion and the bending portion, and the window may include a side surface which overlaps the bending portion and is bent with a predetermined curvature.

In an embodiment, the bending portion may further include a third bending portion which extends from a third side of the flat portion and is bent with a third curvature about a third bending axis parallel to the first bending axis and a fourth bending portion which extends from a fourth side of the flat portion and is bent with a fourth curvature about a fourth bending axis parallel to the second bending axis. In such an embodiment, the third curvature may be greater than the fourth curvature.

In an embodiment, the protective film may further include a plurality of third patterns which extend in a direction parallel to the third bending axis in a third region to overlap the third bending portion and a plurality of fourth patterns which extends in a direction parallel to the fourth bending axis in a fourth region to overlap the fourth bending portion. In such an embodiment, a number of the third patterns may be greater than a number of the fourth patterns.

According to an embodiment, a display device includes a display panel including a flat portion and a bending portion bent from the flat portion and a protective film disposed under the display panel to overlap the flat portion and the bending portion. In such an embodiment, the bending portion includes a first bending portion which extends from a first side of the flat portion and is bent with a first curvature about a first bending axis and a second bending portion which extends from a second side of the flat portion and is bent with a second curvature less than the first curvature about a second bending axis perpendicular to the first bending axis. In such an embodiment, the protective film includes a first pattern portion which extends in a direction parallel to the first bending axis in a first region to overlap the first bending portion and a second pattern portion which extends in a direction parallel to the second bending axis in a second region to overlap the second bending portion. In such an embodiment, a width of the first pattern portion in the direction parallel to the second bending axis is greater than a width of the second pattern portion in the direction parallel to the first bending axis.

In an embodiment, the protective film may include a bending region defined to overlap the first bending portion and the second bending portion and a flat region defined to overlap the flat portion.

In an embodiment, the bending region may include a first patterned region in which the first pattern portion is disposed, a second patterned region in which the second pattern portion is disposed, and an unpatterned region in which the first pattern portion and the second pattern portion are not disposed.

In an embodiment, the first patterned region may have a width in a range from about 60% to about 70% of a width of the bending region.

In an embodiment, the unpatterned region may include a first unpatterned region disposed at one side of the first patterned region and located between the first patterned region and the flat region and a second unpatterned region disposed at an opposite side of the first patterned region which is opposite to the one side of the first patterned region.

In an embodiment, the first unpatterned region may have a width in a range from about 20% to about 30% of a width of the bending region.

In an embodiment, the first pattern portion may include a plurality of first patterns which extend in the direction parallel to the first bending axis, and the second pattern portion may include a plurality of second patterns which extends in the direction parallel to the second bending axis. In such an embodiment, a number of the first patterns may be greater than a number of the second patterns.

### BRIEF DESCRIPTION OF THE DRAWINGS

The above and other features of the disclosure will become apparent by describing in detail embodiments thereof with reference to the accompanying drawings.

FIG. 1 is a perspective view of a display device according to an embodiment of the disclosure.

FIG. 2 is an exploded perspective view of the display device illustrated in FIG. 1.

FIG. 3 is a sectional view of a display panel according to an embodiment of the disclosure.

FIG. 4 is a sectional view of a portion of the display panel according to an embodiment of the disclosure.

FIG. 5 is a plan view of a protective film according to an embodiment of the disclosure.

FIG. 6A is a sectional view of the display panel and the protective film illustrating a portion corresponding to line I-I′ of FIG. 5.

FIG. 6B is a sectional view of the display device illustrating a shape in which a portion of the display device is bent about a bending axis.

FIG. 7A is a sectional view of the display panel and the protective film illustrating a portion corresponding to line II-II′ of FIG. 5.

FIG. 7B is a sectional view of the display device illustrating a shape in which a portion of the display device is bent about a bending axis.

FIG. 8 is an enlarged view of region AA of FIG. 5.

FIG. 9 is a plan view of a protective film according to an alternative embodiment of the disclosure.

FIG. 10A is a sectional view of a display panel and the protective film illustrating a portion corresponding to line III-III′ of FIG. 9.

FIG. 10B is a sectional view of a display device illustrating a shape in which a portion of the display device is bent about a bending axis.

FIG. 11A is a sectional view of the display panel and the protective film illustrating a portion corresponding to line IV-IV′ of FIG. 9.

FIG. 11B is a sectional view of the display device illustrating a shape in which a portion of the display device is bent about a bending axis.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween. Identical reference numerals refer to identical components. Additionally, in the drawings, the thicknesses, proportions, and dimensions of components are exaggerated for effective description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes all of one or more combinations defined by related components. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component.

In addition, terms such as “below”, “under”, “above”, and “over” are used to describe a relationship of components illustrated in the drawings. The terms are relative concepts and are described based on directions illustrated in the drawing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

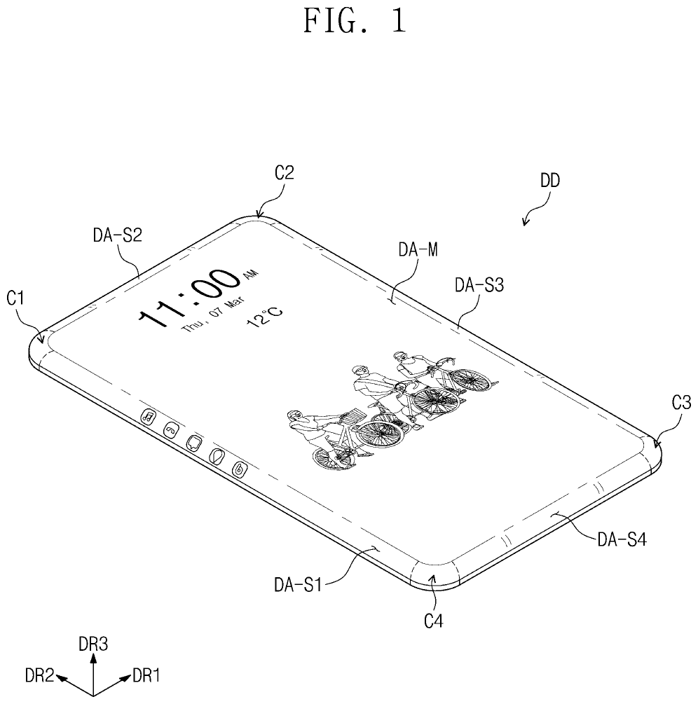

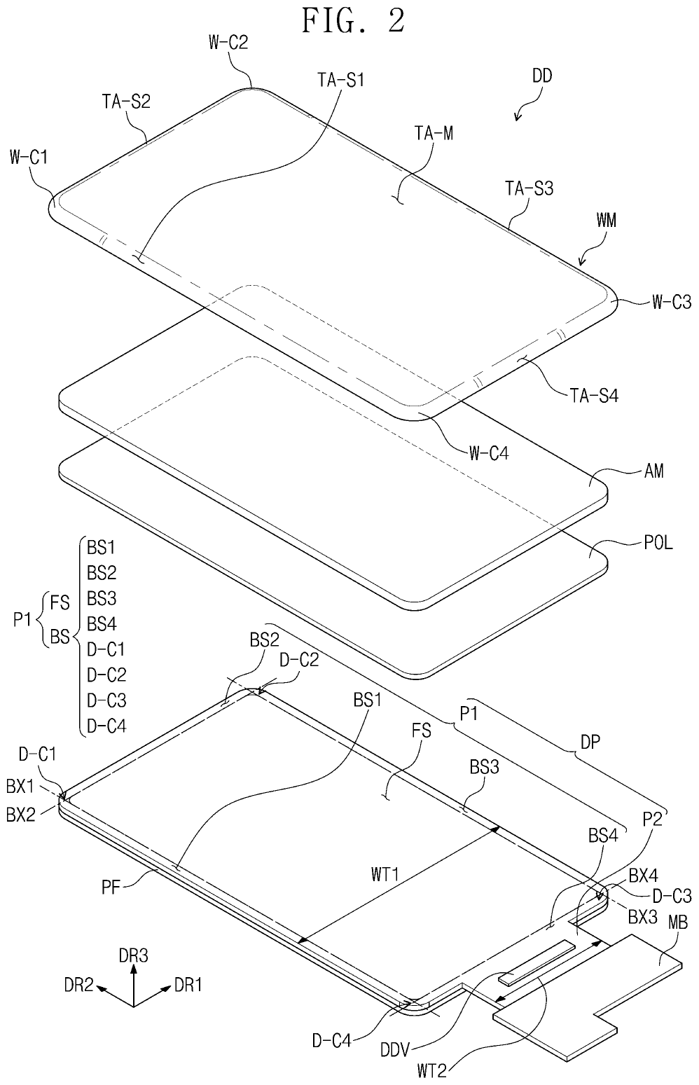

FIG. 1 is a perspective view of a display device according to an embodiment of the disclosure. FIG. 2 is an exploded perspective view of the display device illustrated in FIG. 1.

Referring to FIGS. 1 and 2, an embodiment of the display device DD may be a device that is activated depending on an electrical signal and that displays an image. For example, the display device DD may include a device such as a monitor, a mobile phone, a tablet computer, a car navigation unit, or a game machine. However, the embodiments of the display device DD are illustrative, and the display device DD is not limited to any one device as long as it does not deviate from the spirit and scope of the disclosure. In an embodiment, as shown in FIGS. 1 and 2, the display device DD may be a mobile phone.

A display region may be defined on the display device DD. The display device DD may display an image through the display region and may receive an external input through the display region. The display region of the display device DD may include a main display region DA-M and first to fourth sub-display regions DA-S1, DA-S2, DA-S3, and DA-S4.

The main display region DA-M may be substantially parallel to a plane defined by a first direction DR1 and a second direction DR2. However, without being limited thereto, the main display region DA-M may have a shape concavely or convexly curved with respect to the plane defined by the first direction DR1 and the second direction DR2.

The main display region DA-M may display an image in a third direction DR3 that crosses the first direction DR1 and the second direction DR2. The third direction DR3 may be defined as a thickness direction of the display device DD. Front surfaces (or, upper surfaces) and rear surfaces (or, lower surfaces) of members constituting the display device DD may be opposite each other in the third direction DR3.

The expression “from above the plane” or “in a plan view” used herein may mean that it is viewed in a thickness direction of the display device DD or the third direction DR3. The expression “on a section” or “in a cross-sectional view” used herein may mean that it is viewed in the first direction DR1 or the second direction DR2. In the disclosure, the directions indicated by the first to third directions DR1, DR2, and DR3 may be relative concepts and may be changed to different directions.

The main display region DA-M may have a rectangular shape with short sides extending in the first direction DR1 and long sides extending in the second direction DR2. However, without being limited thereto, the main display region DA-M may have one of various shapes, such as a circular shape, a polygonal shape, and the like, on the plane.

The first to fourth sub-display regions DA-S1, DA-S2, DA-S3, and DA-S4 may be bent from the main display region DA-M. Each of the first to fourth sub-display regions DA-S1, DA-S2, DA-S3, and DA-S4 may be bent with a curvature and may include a curved surface. The first to fourth sub-display regions DA-S1, DA-S2, DA-S3, and DA-S4 may have a same curvature (or a same radius of curvature). However, without being limited thereto, at least some of the first to fourth sub-display regions DA-S1, DA-S2, DA-S3, and DA-S4 may have different curvatures from each other.

The main display region DA-M and the first to fourth sub-display regions DA-S1, DA-S2, DA-S3, and DA-S4 may be adjacent to each other and may implement (or collectively define) a continuous display region. The first sub-display region DA-S1 and the third sub-display region DA-S3 may extend from the long sides of the main display region DA-M that are parallel to the second direction DR2, and the second sub-display region DA-S2 and the fourth sub-display region DA-S4 may extend from the short sides of the main display region DA-M that are parallel to the first direction DR1.

The first sub-display region DA-S1 and the third sub-display region DA-S3 may extend in the second direction DR2 and may be spaced apart from each other in the first direction DR1 with the main display region DA-M therebetween. The second sub-display region DA-S2 and the fourth sub-display region DA-S4 may extend in the first direction DR1 and may be spaced apart from each other in the second direction DR2 with the main display region DA-M therebetween.

FIG. 1 illustrates an embodiment including the four sub-display regions DA-S1, DA-S2, DA-S3, and DA-S4 extending from the four sides of the main display region DA-M. However, without being limited thereto, the display region of the display device DD may include a sub-display region bent while extending from at least one side among the four sides of the main display region DA-M. For example, the display device DD according to an embodiment may include only some of the four sub-display regions DA-S1, DA-S2, DA-S3, and DA-S4.

The display device DD may include first to fourth display corner portions C1, C2, C3, and C4 disposed between the first to fourth sub-display regions DA-S1, DA-S2, DA-S3, and DA-S4. The first to fourth sub-display regions DA-S1, DA-S2, DA-S3, and DA-S4 and the first to fourth display corner portions C1, C2, C3, and C4 may be connected together to surround the main display region DA-M.

The first display corner portion C1 may be a portion that is disposed between the first sub-display region DA-S1 and the second sub-display region DA-S2 and that connects the first sub-display region DA-S1 and the second sub-display region DA-S2 extending in directions crossing each other and has a curvature. The second display corner portion C2 may be a portion that is disposed between the second sub-display region DA-S2 and the third sub-display region DA-S3 and that connects the second sub-display region DA-S2 and the third sub-display region DA-S3 extending in directions crossing each other and has a curvature. The third display corner portion C3 may be a portion that is disposed between the third sub-display region DA-S3 and the fourth sub-display region DA-S4 and that connects the third sub-display region DA-S3 and the fourth sub-display region DA-S4 extending in directions crossing each other and has a curvature. The fourth display corner portion C4 may be a portion that is disposed between the fourth sub-display region DA-S4 and the first sub-display region DA-S1 and that connects the fourth sub-display region DA-S4 and the first sub-display region DA-S1 extending in directions crossing each other and has a curvature.

The first to fourth display corner portions C1, C2, C3, and C4 may correspond to the corners of the display device DD, respectively. In such an embodiment, since the first to fourth display corner portions C1, C2, C3, and C4 have the curvatures, respectively, the corners of the display device DD may have a round shape rather than an angled shape.

Referring to FIG. 2, an embodiment of the display device DD may include a window WM, a display panel DP, a driver DDV, a circuit board MB, a protective film PF, an anti-reflective layer POL, and an adhesive member AM.

The window WM may be disposed on the display panel DP. The window WM may be coupled with the display panel DP through a lamination process. The window WM may cover the anti-reflective layer POL and the display panel DP and may protect the anti-reflective layer POL and the display panel DP from an external impact and a scratch.

The window WM may include an optically clear insulating material. In an embodiment, for example, the window WM may include a base film containing glass or a synthetic resin. The window WM may have a single-layer structure or a multi-layer structure. In an embodiment, for example, the window WM having a multi-layer structure may include synthetic resin films coupled by an adhesive, or may include a glass film and a synthetic resin film coupled by an adhesive. The window WM may further include functional layers, such as an anti-fingerprint layer, a phase control layer, and a hard coating layer, on the base film.

The window WM may include a transmissive region, and the transmissive region of the window WM may correspond to the display region of the display device DD illustrated in FIG. 1. The transmissive region of the window WM may transmit an image output from the display panel DP, and a user may visually recognize the image from outside the display device DD. The window WM may include a main transmissive surface TA-M and first to fourth side transmissive surfaces TA-S1, TA-S2, TA-S3, and TA-S4.

The main transmissive surface TA-M may correspond to the main display region DA-M illustrated in FIG. 1. The main transmissive surface TA-M may include a plane substantially parallel to the plane defined by the first direction DR1 and the second direction DR2.

Each of the first to fourth side transmissive surfaces TA-S1, TA-S2, TA-S3, and TA-S4 may be bent with a curvature from the main transmissive surface TA-M. Accordingly, each of the first to fourth side transmissive surfaces TA-S1, TA-S2, TA-S3, and TA-S4 may include a curved surface extending from the main transmissive surface TA-M. The first to fourth side transmissive surfaces TA-S1, TA-S2, TA-S3, and TA-S4 may correspond to the first to fourth sub-display regions DA-S1, DA-S2, DA-S3, and DA-S4 illustrated in FIG. 1, respectively.

The main transmissive surface TA-M and the first to fourth side transmissive surfaces TA-S1, TA-S2, TA-S3, and TA-S4 may be adjacent to each other and may implement a continuous transmissive region. The first side transmissive surface TA-S1 and the third side transmissive surface TA-S3 may extend in the second direction DR2 and may be spaced apart from each other in the first direction DR1 with the main transmissive surface TA-M therebetween. The second side transmissive surface TA-S2 and the fourth side transmissive surface TA-S4 may extend in the first direction DR1 and may be spaced apart from each other in the second direction DR2 with the main transmissive surface TA-M therebetween.

The window WM may include first to fourth window corner portions W-C1, W-C2, W-C3, and W-C4 disposed between the first to fourth side transmissive surfaces TA-S1, TA-S2, TA-S3, and TA-S4. The first to fourth window corner portions W-C1, W-C2, W-C3, and W-C4 may substantially correspond to the first to fourth display corner portions C1, C2, C3, and C4 of the display device DD illustrated in FIG. 1. The first to fourth side transmissive surfaces TA-S1, TA-S2, TA-S3, and TA-S4 and the first to fourth window corner portions W-C1, W-C2, W-C3, and W-C4 may be connected together to surround the main transmissive surface TA-M.

The first window corner portion W-C1 may connect the first side transmissive surface TA-S1 and the second side transmissive surface TA-S2 that extend in directions crossing each other. The second window corner portion W-C2 may connect the second side transmissive surface TA-S2 and the third side transmissive surface TA-S3 that extend in directions crossing each other. The third window corner portion W-C3 may connect the third side transmissive surface TA-S3 and the fourth side transmissive surface TA-S4 that extend in directions crossing each other. The fourth window corner portion W-C4 may connect the fourth side transmissive surface TA-S4 and the first side transmissive surface TA-S1 that extend in directions crossing each other. The first to fourth window corner portions W-C1, W-C2, W-C3, and W-C4 may be portions having curvatures, respectively.

The first side transmissive surface TA-S1 and the third side transmissive surface TA-S3 may be bent with a same curvature as each other. The second side transmissive surface TA-S2 and the fourth side transmissive surface TA-S4 may be bent with a same curvature as each other. The first side transmissive surface TA-S1 and the third side transmissive surface TA-S3 may have a curvature different from that of the second side transmissive surface TA-S2 and the fourth side transmissive surface TA-S4. Accordingly, the window corner portions W-C1, W-C2, W-C3, and W-C4 may connect the first and third side transmissive surfaces TA-S1 and TA-S3 extending in the second direction DR2 and defining long sides of the window WM and the second and fourth side transmissive surfaces TA-S2 and TA-S4 extending in the first direction DR1 and defining short sides of the window WM and may be formed as double curvature points having different curvatures.

The display panel DP may be disposed under the window WM. The display panel DP may display an image depending on an electrical signal. In some embodiments, the display panel DP may transmit and receive information about an external input. The display panel DP according to an embodiment may be an emissive display panel, but is not particularly limited thereto. For example, the display panel DP may be an organic light emitting display panel, an inorganic light emitting display panel, or a quantum dot light emitting display panel. An emissive layer of the organic light emitting display panel may include an organic light emitting material, and an emissive layer of the inorganic light emitting display panel may include an inorganic light emitting material. An emissive layer of the quantum dot light emitting display panel may include quantum dots and quantum rods. Hereinafter, for convenience of description, embodiment where the display panel DP is an organic light emitting display panel will be described in detail.

The display panel DP may include a first part P1 and a second part P2. The first part P1 and the second part P2 may be adjacent to each other in the second direction DR2. The second part P2 may be a part protruding and extending from the first part P1 in the second direction DR2, and the first part P1 and the second part P2 may have a continuous shape (or, an integrated shape).

The first part P1 of the display panel DP may include a flat portion FS and a bending portion BS. The bending portion BS may include first to fourth bending portions BS1, BS2, BS3, and BS4 and first to fourth corner portions D-C1, D-C2, D-C3, and D-C4 disposed between the first to fourth bending portions BS1, BS2, BS3, and BS4.

The first part P1 of the display panel DP may overlap the transmissive region of the window WM. Pixels may be disposed in the first part P1 of the display panel DP. The pixels may be disposed in the flat portion FS and the bending portion BS. In such an embodiment, the pixels may be disposed in the flat portion FS, the first to fourth bending portions BS1, BS2, BS3, and BS4, and the first to fourth corner portions D-C1, D-C2, D-C3, and D-C4. The flat portion FS, the first to fourth bending portions BS1, BS2, BS3, and BS4, and the first to fourth corner portions D-C1, D-C2, D-C3, and D-C4 may be adjacent to each other and may implement an integrated continuous display region.

An arrangement of the pixels in the first part P1 of the display panel DP may be designed in various ways. Each of the pixels may be constituted by a light emitting element, transistors (e.g., a switching transistor and a drive transistor), and at least one capacitor and may include a pixel drive circuit connected with the light emitting element. An image output through the pixels disposed in the first part P1 of the display panel DP may be output through the transmissive region of the window WM and may be visible from the outside.

The flat portion FS may include a plane substantially parallel to the plane defined by the first direction DR1 and the second direction DR2. The flat portion FS may overlap the main transmissive surface TA-M. The entire surface of the flat portion FS may be defined as a display region. However, embodiments are not limited thereto, and part of the flat portion FS may be a non-display region.

The first to fourth bending portions BS1, BS2, BS3, and BS4 may extend from one side surface of the flat portion FS. The first to fourth bending portions BS1, BS2, BS3, and BS4 may correspond to edges of the display panel DP, respectively. The first to fourth bending portions BA-S1, BA-S2, BA-S3, and BA-S4 may overlap the first to fourth side transmissive surfaces TA-S1, TA-S2, TA-S3, and TA-S4 of the window WM, respectively. The first to fourth bending portions BA-S1, BA-S2, BA-S3, and BA-S4 may be defined as a display region. In some embodiments, the first to fourth bending portions BA-S1, BA-S2, BA-S3, and BA-S4 may further include a non-display region adjacent to the display region.

When the display panel DP is coupled to the window WM, the bending portion BS may be bent by extending from the flat portion FS and may include a curved surface having a curvature. The first bending portion BS1 may be a portion that corresponds to the first side transmissive surface TA-S1 and that is bent about a first bending axis BX1 parallel to the second direction DR2. The second bending portion BS2 may be bent about a second bending axis BX2 parallel to the first direction DR1 so as to correspond to the second side transmissive surface TA-S2. The third bending portion BS3 may be bent about a third bending axis BX3 parallel to the second direction DR2 so as to correspond to the third side transmissive surface TA-S3. The fourth bending portion BS4 may be bent about a fourth bending axis BX4 parallel to the first direction DR1 so as to correspond to the fourth side transmissive surface TA-S4. The first bending portion BS1 and the third bending portion BS3 may be bent with a same curvature as each other. The second bending portion BS2 and the fourth bending portion BS4 may be bent with a same curvature as each other. The first bending portion BS1 and the third bending portion BS3 may have a curvature different from that of the second bending portion BS2 and the fourth bending portion BS4.

The first bending portion BS1 and the third bending portion BS3 may extend in the second direction DR2 and may be spaced apart from each other in the first direction DR1 with the flat portion FS therebetween. The first bending portion BS1 and the third bending portion BS3 may define long sides of the display panel DP that are parallel to the second direction DR2.

The second bending portion BS2 and the fourth bending portion BS4 may extend in the first direction DR1 and may be spaced apart from each other in the second direction DR2 with the flat portion FS therebetween. The second bending portion BS2 and the fourth bending portion BS4 may define short sides of the display panel DP that are parallel to the first direction DR1.

The first to fourth corner portions D-C1, D-C2, D-C3, and D-C4 may be disposed between the first to fourth bending portions BS1, BS2, BS3, and BS4. The first to fourth corner portions D-C1, D-C2, D-C3, and D-C4 may correspond to the corners of the display panel DP, respectively. The first to fourth bending portions BS1, BS2, BS3, and BS4 and the first to fourth corner portions D-C1, D-C2, D-C3, and D-C4 may be connected together to surround the flat portion FS. The first to fourth corner portions D-C1, D-C2, D-C3, and D-C4 may overlap the first to fourth window corner portions W-C1, W-C2, W-C3, and W-C4, respectively. When the display panel DP is coupled to the window WM, each of the first to fourth corner portions D-C1, D-C2, D-C3, and D-C4 may be bent with a curvature.

The first corner portion D-C1 may connect the first bending portion BS1 and the second bending portion BS2 that extend in directions crossing each other. The second corner portion D-C2 may connect the second bending portion BS2 and the third bending portion BS3 that extend in directions crossing each other. The third corner portion D-C3 may connect the third bending portion BS3 and the fourth bending portion BS4 that extend in directions crossing each other. The fourth corner portion D-C4 may connect the fourth bending portion BS4 and the first bending portion BS1 that extend in directions crossing each other. The first to fourth corner portions D-C1, D-C2, D-C3, and D-C4 may be portions having curvatures, respectively.

Outer surfaces of the first to fourth corner portions D-C1, D-C2, D-C3, and D-C4 may connect the short sides of the display panel DP extending in the first direction DR1 and the long sides of the display panel DP extending in the second direction DR2 and may include curved surfaces having at least one curvature. According to an embodiment, the first to fourth corner portions D-C1, D-C2, D-C3, and D-C4 may be formed as double curvature points having different curvatures.

The second part P2 may extend from the fourth bending portion BS4. The second part P2 may extend parallel to the second direction DR2 from a side surface of the fourth bending portion BS4 that is parallel to the first direction DR1. The second part P2 may be bent about a bending axis parallel to the first direction DR1 toward a rear surface of the display panel DP that corresponds to the first part P1. As the second part P2 is bent, the second part P2 may overlap the first part P1 on the plane or in the third direction DR3.

The width WT1 of the first part P1 in the first direction DR1 may be greater than the width WT2 of the second part P2 in the first direction DR1. Since the second part P2 has a small width in the direction parallel to the bending axis, the second part P2 may be easily bent. However, embodiments are not limited thereto, and alternatively, the second part P2 of the display panel DP may be omitted. In such an embodiment, the side surface of the fourth bending portion BS4 may correspond to an end of the display panel DP.

The protective film PF may be disposed under the display panel DP, that is, on the rear surface of the display panel DP. The protective film PF may be disposed to overlap the first part P1 of the display panel DP. In an embodiment, the protective film PF may be disposed to overlap the flat portion FS and the bending portion BS. The protective film PF may be attached to the rear surface of the display panel DP through an adhesive layer. The protective film PF may prevent the rear surface of the display panel DP from being damaged in a process.

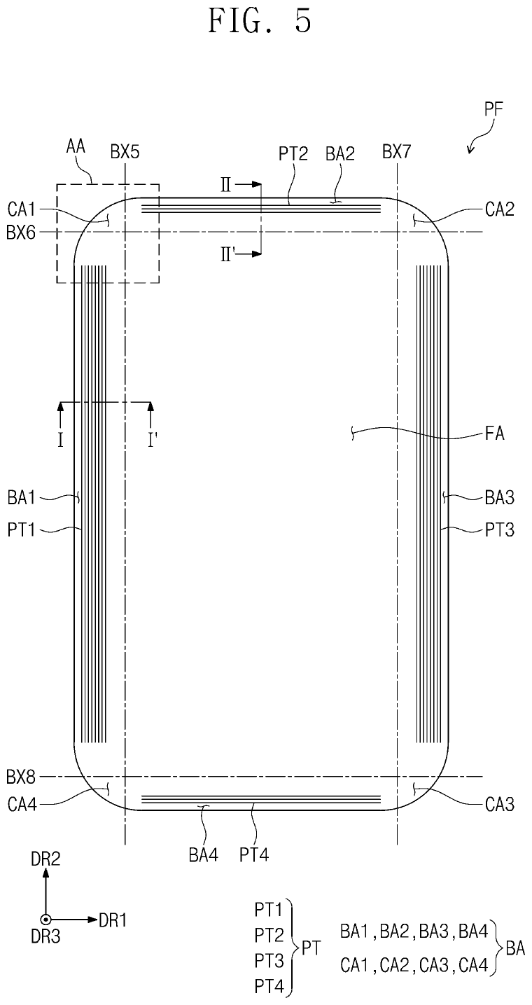

In an embodiment, the protective film PF may include a plurality of patterns PT1, PT2, PT3, and PT4 (refer to FIG. 5) in a region overlapping the bending portion BS. In such an embodiment, since the plurality of patterns PT1, PT2, PT3, and PT4 are formed on the protective film PF, when the display panel DP is attached to the window WM, a buckling phenomenon in which the corner portions D-C1, D-C2, D-C3, and D-C4 of the display panel DP are attached while being wrinkled or the occurrence of a crack may be effectively prevented. Detailed description thereabout will be given below.

The driver DDV may be disposed on the second part P2. The driver DDV may include a timing control circuit, a data drive circuit, or the like. The driver DDV may be provided as an integrated circuit chip (a driver chip) mounted on the second part P2. However, without being limited thereto, the driver DDV may be provided separately from the display panel DP and may be mounted on a flexible circuit board electrically connected to the display panel DP.

The circuit board MB may be coupled to the second part P2. The circuit board MB may be coupled closer to a lower end of the second part P2 than the driver DDV. The circuit board MB may be electrically connected to the second part P2 and may provide signals for driving the display panel DP to the driver DDV. As the second part P2 is bent, the circuit board MB may be disposed to overlap the first part P1 of the display panel DP on the plane. Alternatively, without being limited thereto, the second part P2 may be omitted, and the circuit board MB may be directly connected to the first part P1, or may be connected to the display panel DP through a separate flexible circuit board.

The anti-reflective layer POL may be disposed on the display panel DP. In an embodiment, the anti-reflective layer POL may be directly disposed on the display panel DP without a separate adhesive member. In such an embodiment, the anti-reflective layer POL may be formed, through a continuous process, on a base surface provided by the display panel DP. Alternatively, without being limited thereto, the anti-reflective layer POL may be coupled with the display panel DP through a separate adhesive member.

The anti-reflective layer POL may decrease the reflectance of external light incident from above the display device DD. The anti-reflective layer POL may include various embodiments that decrease the reflectance of external light.

The anti-reflective layer POL according to an embodiment may include a phase retarder and a polarizer. The phase retarder may include a 2/2 phase retarder and/or a 2/4 phase retarder. The phase retarder and the polarizer may be of a film type or a liquid crystal coating type. The film type polarizer may include a stretchable synthetic resin film, and the liquid crystal coating type polarizer may include liquid crystals arranged in a predetermined arrangement. Alternatively, without being limited thereto, the phase retarder and the polarizer may be implemented with one polarizer film.

The anti-reflective layer POL according to an embodiment may include a destructive interference structure. In an embodiment, for example, the destructive interference structure may include a first reflective layer and a second reflective layer that are disposed on different layers. First reflected light reflected by the first reflective layer and second reflected light reflected by the second reflective layer may destructively interfere with each other, and thus the anti-reflective layer POL may decrease the reflectance of external light.

The anti-reflective layer POL according to an embodiment may include color filters. The color filters may be disposed to correspond to the arrangement and light emission colors of the pixels included in the display panel DP. The anti-reflective layer POL may filter external light incident from above the display device DD into colors corresponding to the light emission colors of the pixels. The anti-reflective layer POL may further include a black matrix adjacent to the color filters.

The adhesive member AM may be disposed between the anti-reflective layer POL and the window WM. The display panel DP and the anti-reflective layer POL may be coupled to the window WM through the adhesive member AM. The adhesive member AM may be a transparent adhesive member such as a pressure sensitive adhesive (PSA) film, an optically clear adhesive (OCA) film, or an optically clear resin (OCR).

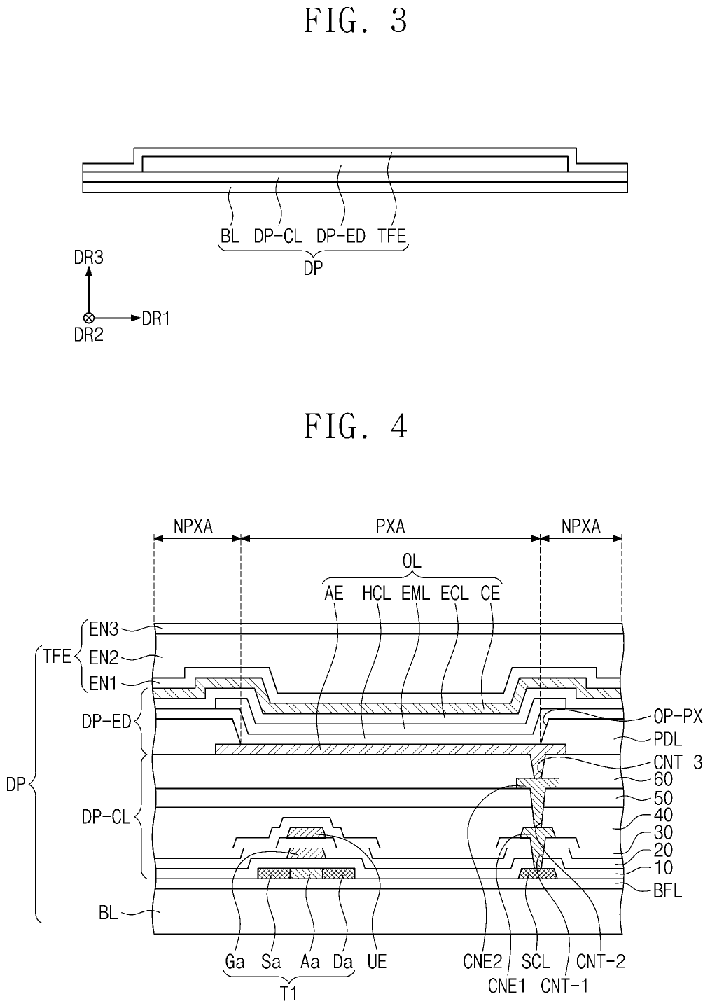

FIG. 3 is a sectional view of the display panel DP according to an embodiment of the disclosure.

Referring to FIG. 3, an embodiment of the display panel DP may include a base layer BL, a circuit layer DP-CL, a display element layer DP-ED, and an encapsulation layer TFE.

The base layer BL may provide a base surface on which the circuit layer DP-CL is disposed. The base layer BL may be a rigid substrate, or may be a flexible substrate that can be bent, folded, or rolled. In an embodiment, for example, the base layer BL may be a glass substrate, a metal substrate, a polymer substrate, or the like.

The base layer BL may have a multi-layer structure. In an embodiment, for example, the base layer BL may include synthetic resin layers and at least one inorganic layer disposed between the synthetic resin layers. The synthetic resin layers of the base layer BL may include at least one selected from an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin. However, the material of the base layer BL is not limited thereto.

The circuit layer DP-CL may be disposed on the base layer BL. The circuit layer DP-CL may include an insulating pattern, a semiconductor pattern, and a conductive pattern that form a pixel drive circuit of a pixel, a drive line, and a pad. In a manufacturing step of the display panel DP, the circuit layer DP-CL may be formed by forming an insulating layer, a semiconductor layer, and a conductive layer on the base layer BL through coating or deposition and thereafter making the insulating layer, the semiconductor layer, and the conductive layer subject to patterning by performing photolithography a plurality of times.

The display element layer DP-ED may be disposed on the circuit layer DP-CL. The display element layer DP-ED may include light emitting elements constituting pixels. The light emitting elements may be electrically connected with a pixel drive circuit of the circuit layer DP-CL. The light emitting elements may include an organic light emitting element, an inorganic light emitting element, a micro light emitting diode (LED), or a nano LED and are not limited to any one as long as the amount of light is able to be controlled depending on an electrical signal.

The encapsulation layer TFE may be disposed on the display element layer DP-ED and may seal the display element layer DP-ED. The encapsulation layer TFE may include at least one thin film for improving the optical efficiency of the display element layer DP-ED or protecting the display element layer DP-ED. In an embodiment, for example, the encapsulation layer TFE may include at least one of an inorganic film and an organic film. The inorganic film of the encapsulation layer TFE may protect the display element layer DP-ED from moisture/oxygen. The organic film of the encapsulation layer TFE may protect the display element layer DP-ED from foreign matter such as dust particles.

The inorganic film of the encapsulation layer TFE may include at least one selected from aluminum oxide, titanium oxide, silicon oxide, silicon nitride, silicon oxy-nitride, zirconium oxide, and hafnium oxide. The organic film of the encapsulation layer TFE may include an acrylate-based resin. However, the material of the encapsulation layer TFE is not limited thereto.

In an embodiment, the display panel DP may further include an input sensing layer that is disposed on the encapsulation layer TFE and that senses an external input. In an embodiment, the input sensing layer may be directly disposed on the encapsulation layer TFE. In such an embodiment, the input sensing layer may be formed on an upper surface of the encapsulation layer TFE through a continuous process. Alternatively, without being limited thereto, the input sensing layer may be coupled onto the encapsulation layer TFE through a separate adhesive member.

The input sensing layer may obtain coordinate information of an external input applied from outside the display device DD (refer to FIG. 1). The external input may include various types of inputs, such as force, pressure, temperature, light, and the like. For example, the external input may be a hand of the user or an electronic pen in contact with the display device DD (refer to FIG. 1), or may include an input such as hovering applied in proximity to the display device DD (refer to FIG. 1).

The input sensing layer may be driven in various ways to sense an external input applied from outside the display device DD (refer to FIG. 1). For example, the input sensing layer may be operated by a capacitance sensing method, a resistance sensing method, an infrared sensing method, a sound-wave sensing method, or a pressure sensing method and is not limited to any one as long as an external input is able to be sensed.

FIG. 4 is a sectional view of a portion of the display panel according to an embodiment of the disclosure. Particularly, FIG. 4 illustrates the configuration of the display panel DP shown in FIG. 3 in greater detail. Hereinafter, any repetitive detailed descriptions of the same or like elements as those described above with reference to FIG. 3 will be omitted or simplified.

The display panel DP may include a plurality of pixels. Each of the pixels may include at least one transistor T1 and a light emitting element OL. FIG. 4 illustrates a region in which the transistor T1 and the light emitting element OL of one of the pixels of the display panel DP are disposed. Referring to FIG. 4, the display panel DP may include the base layer BL, the circuit layer DP-CL, the display element layer DP-ED, and the encapsulation layer TFE.

The base layer BL may provide a base surface on which the circuit layer DP-CL is disposed. In an embodiment, the base layer BL may include a synthetic resin layer. The synthetic resin layer may be formed on a support substrate that is used in manufacture of the display panel DP, and a conductive layer and an insulating layer may be formed on the synthetic resin layer. Thereafter, the support substrate may be removed, and the synthetic resin layer from which the support substrate is removed may correspond to the base layer BL.

At least one inorganic layer may be disposed on an upper surface of the base layer BL. The inorganic layer may constitute a barrier layer and/or a buffer layer. FIG. 4 illustrates an embodiment where a buffer layer BFL is disposed on the base layer BL. The buffer layer BFL may improve a coupling force between the base layer BL and a semiconductor pattern of the circuit layer DP-CL.

The circuit layer DP-CL may be disposed on the buffer layer BFL. The circuit layer DP-CL may include at least one insulating layer and a circuit element. The circuit element may include a signal line and a pixel drive circuit. The circuit layer DP-CL may be formed through a process of forming an insulating layer, a semiconductor layer, and a conductive layer by coating, deposition, or the like and a process of making the insulating layer, the semiconductor layer, and the conductive layer subject to patterning by photolithography.

In an embodiment, as shown in FIG. 4, the circuit layer DP-CL may include the transistor T1, a connecting signal line SCL, connecting electrodes CNE1 and CNE2, and a plurality of insulating layers 10 to 60. The plurality of insulating layers 10 to 60 may include the first to sixth insulating layers 10 to 60 sequentially stacked on the buffer layer BFL. Each of the first to sixth insulating layers 10 to 60 may include one of an inorganic layer and an organic layer.

The transistor T1 may include a semiconductor pattern including a source region Sa, an active region Aa, and a drain region Da, and a gate electrode Ga. In an embodiment, the semiconductor pattern of the transistor T1 may include poly silicon. Alternatively, without being limited thereto, the semiconductor pattern may include amorphous silicon or metal oxide.

The semiconductor pattern may be divided into a plurality of regions depending on conductivities. In an embodiment, for example, the semiconductor pattern may have different electrical properties depending on whether doping is performed or whether metal oxide is reduced. A high-conductivity region of the semiconductor pattern may serve as an electrode or a signal line and may correspond to the source region Sa and the drain region Da of the transistor T1. A non-doped or non-reduced region having relatively low conductivity may correspond to the active region Aa (or, the channel region) of the transistor T1.

The connecting signal line SCL may be formed from (or defined by portions of) the semiconductor pattern and may be disposed in (or directly on) a same layer as the source region Sa, the active region Aa, and the drain region Da of the transistor T1. According to an embodiment, the connecting signal line CSL may be electrically connected to the drain region Da of the transistor T1 on the plane.

The first insulating layer 10 may cover the semiconductor pattern of the circuit layer DP-CL. The gate electrode Ga may be disposed on the first insulating layer 10. The gate electrode Ga may overlap the active region Aa on the plane. The gate electrode Ga may function as a mask in a process of doping the semiconductor pattern. An upper electrode UE may be disposed on the second insulating layer 20. The upper electrode UE may overlap the gate electrode Ga on the plane.

The first connecting electrode CNE1 and the second connecting electrode CNE2 may be disposed between the transistor T1 and the light emitting element OL and may electrically connect the transistor T1 and the light emitting element OL to each other. The first connecting electrode CNE1 may be disposed on the third insulating layer 30 and may be connected to the connecting signal line SCL through a contact hole CNT-1 defined through the first to third insulating layers 10 to 30. The second connecting electrode CNE2 may be disposed on the fifth insulating layer 50 and may be connected to the first connecting electrode CNE1 through a contact hole CNT-2 defined through the fourth and fifth insulating layers 40 and 50.

The display element layer DP-ED may be disposed on the circuit layer DP-CL. The display element layer DP-ED may include the light emitting element OL and a pixel defining layer PDL. The light emitting element OL may include a first electrode AE, a second electrode CE, and an intermediate layer disposed between the first electrode AE and the second electrode CE. The first electrode AE and the second electrode CE may include or be formed of a conductive material. In an embodiment, the intermediate layer may include at least one organic layer, and in such an embodiment, the intermediate layer may include a hole control layer HCL, an emissive layer EML, and an electron control layer ECL as shown in FIG. 4. However, this is merely illustrative, and the intermediate layer may further include an additional layer, in addition to the hole control layer HCL, the emissive layer EML, and the electron control layer ECL. Alternatively, at least one selected from the hole control layer HCL, the emissive layer EML, and the electron control layer ECL may be omitted, and the disclosure is not limited to any one embodiment.

The first electrode AE and the pixel defining layer PDL may be disposed on the sixth insulating layer 60. The first electrode AE may be connected to the second connecting electrode CNE2 through a contact hole CNT-3 defined through the sixth insulating layer 60. The pixel defining layer PDL may be provided with a light emitting opening OP-PX defined therein through which at least a portion of the first electrode AE is exposed. The portion of the first electrode AE exposed by the light emitting opening OP-PX may correspond to an emissive region PXA. A non-emissive region NPXA may surround the emissive region PXA.

The hole control layer HCL and the electron control layer ECL may be commonly disposed in the emissive region PXA and the non-emissive region NPXA. The emissive layer EML may have (or be formed in) a pattern form to correspond to the light emitting opening OP-PX. The emissive layer EML in the pattern form may be formed by using a deposition apparatus.

When compared to the hole control layer HCL and the electron control layer ECL that have a film form, the emissive layer EML may be deposited in a different way. In an embodiment, for example, the hole control layer HCL and the electron control layer ECL may be commonly formed for the pixels by using a mask referred to as an open mask. The emissive layer EML may be differently formed depending on the pixels by using a mask referred to as a fine metal mask (FMM).

The encapsulation layer TFE may include a plurality of thin films. The encapsulation layer TFE according to an embodiment may include first to third thin films EN1, EN2, and EN3 sequentially stacked one above another. Each of the first to third thin films EN1, EN2, and EN3 may include one of an inorganic film and an organic film. The inorganic film may protect the light emitting element OL from moisture and/or oxygen. The organic film may protect the light emitting element OL from foreign matter such as dust particles. However, a configuration of the encapsulation layer TFE is not limited to that illustrated in the drawing as long as the encapsulation layer TFE is capable of protecting the light emitting element OL or improving light emission efficiency.

FIG. 5 is a plan view of the protective film according to an embodiment of the disclosure.

Referring to FIG. 5, an embodiment of the protective film PF may include a bending region BA and a flat region FA. The flat region FA may correspond to the flat portion FS of the display panel DP illustrated in FIG. 2. That is, the flat region FA may overlap the flat portion FS on the plane.

The bending region BA may include first to fourth bending regions BA1, BA2, BA3, and BA4 and first to fourth corner regions CA1, CA2, CA3, and CA4. In an embodiment, the first to fourth bending regions BA1, BA2, BA3, and BA4 may correspond to the first to fourth bending portions BS1, BS2, BS3, and BS4 of the display panel DP illustrated in FIG. 2. That is, the first bending region BA1, the second bending region BA2, the third bending region BA3, and the fourth bending region BA4 may overlap the first bending portion BS1, the second bending portion BS2, the third bending portion BS3, and the fourth bending portion BS4, respectively.

The first bending region BA1 may correspond to the first bending portion BS1 and may be bent about a fifth bending axis BX5 parallel to the second direction DR2 together with the first bending portion BS1. The second bending region BA2 may correspond to the second bending portion BS2 and may be bent about a sixth bending axis BX6 parallel to the first direction DR1 together with the second bending portion BS2. The third bending region BA3 may correspond to the third bending portion BS3 and may be bent about a seventh bending axis BX7 parallel to the second direction DR2 together with the third bending portion BS3. The fourth bending region BA4 may correspond to the fourth bending portion BS4 and may be bent about an eighth bending axis BX8 parallel to the first direction DR1 together with the fourth bending portion BS4.

The first to fourth corner regions CA1, CA2, CA3, and CA4 may correspond to the first to fourth corner portions D-C1, D-C2, D-C3, and D-C4 illustrated in FIG. 2. That is, the first corner region CA1, the second corner region CA2, the third corner region CA3, and the fourth corner region CA4 may overlap the first corner portion D-C1, the second corner portion D-C2, the third corner portion D-C3, and the fourth corner portion D-C4, respectively.

According to an embodiment of the disclosure, the protective film PF may include patterns PT. The patterns PT may include the first pattern PT1 defined or formed in the first bending region BA1, the second pattern PT2 defined or formed in the second bending region BA2, the third pattern PT3 defined or formed in the third bending region BA3, and the fourth pattern PT4 defined or formed in the fourth bending region BA4.

A plurality of first patterns PT1, a plurality of second patterns PT2, a plurality of third patterns PT3, and a plurality of fourth patterns PT4 may be provided. The first patterns PT1 and the third patterns PT3 may extend in the second direction DR2 and may be arranged in the first direction DR1. The first patterns PT1 and the third patterns PT3 may be spaced apart from each other in the first direction DR1 with the flat region FA therebetween. The second patterns PT2 and the fourth patterns PT4 may extend in the first direction DR1 and may be arranged in the second direction DR2. The second patterns PT2 and the fourth patterns PT4 may be spaced apart from each other in the second direction DR2 with the flat region FA therebetween.

The number of first patterns PT1 may vary depending on the curvature of the first bending portion BS1 (refer to FIG. 2). In an embodiment, the number of first patterns PT1 may be adjusted depending on a first curvature with which the first bending portion BS1 is bent. In such an embodiment, for example, as the first curvature is decreased, the number of first patterns PT1 may be decreased, and as the first curvature is increased, the number of first patterns PT1 may be increased. This may be identically applied to the second patterns PT2, the third patterns PT3, and the fourth patterns PT4.

According to an embodiment of the disclosure, the number of first patterns PT1 may differ from the number of second patterns PT2. In an embodiment, the number of first patterns PT1 may be greater than the number of second patterns PT2. In such an embodiment, as the first curvature is formed to be greater than a second curvature, the number of first patterns PT1 may be greater than the number of second patterns PT2. In an embodiment, for example, the number of first patterns PT1 may be eight, and the number of second patterns PT2 may be three. The number of third patterns PT3 may differ from the number of fourth patterns PT4. In an embodiment, the number of third patterns PT3 may be greater than the number of fourth patterns PT4. In such an embodiment, as a third curvature is formed to be greater than a fourth curvature, the number of third patterns PT3 may be greater than the number of fourth patterns PT4. In an embodiment, for example, the number of third patterns PT3 may be eight, and the number of fourth patterns PT4 may be three. The number of first patterns PT1 may be equal to the number of third patterns PT3, and the number of second patterns PT2 may be equal to the number of fourth patterns PT4.

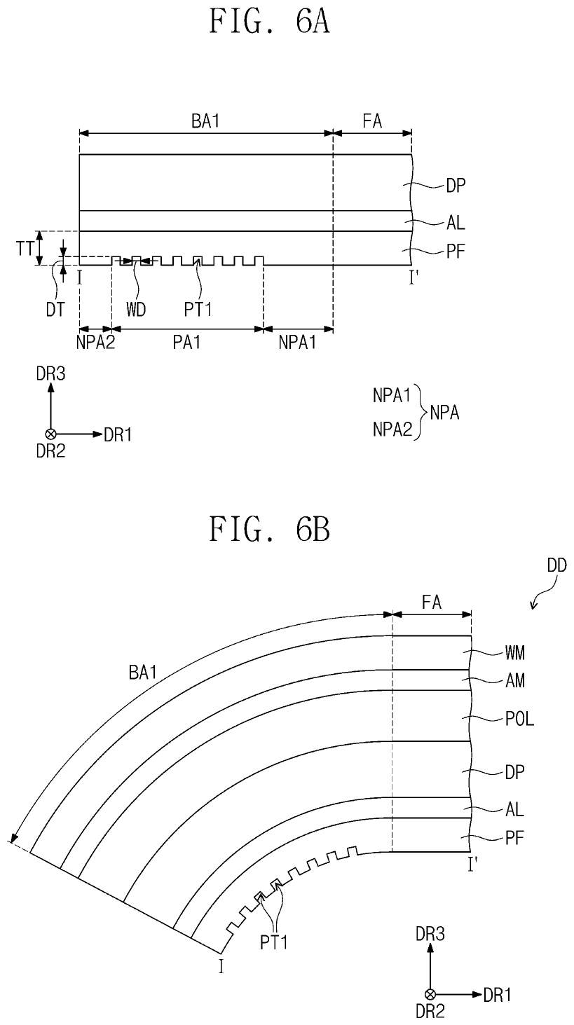

FIG. 6A is a sectional view of the display panel and the protective film illustrating a portion corresponding to line I-I′ of FIG. 5. FIG. 6B is a sectional view of the display device illustrating a shape in which a portion of the display device is bent about a bending axis.

Referring to FIGS. 6A and 6B, an embodiment of the display device DD may include the display panel DP, an adhesive layer AL, the protective film PF, the adhesive member AM, and the window WM, which are substantially the same as those described above.

The protective film PF may be coupled to the display panel DP through the adhesive layer AL disposed on the rear surface of the display panel DP. The adhesive layer AL may include a transparent adhesive such as a PSA film, an OCA film, or an OCR.

The protective film PF may include an upper surface making contact with the adhesive layer AL and a lower surface facing away from the upper surface. The upper surface of the protective film PF may be closer to the rear surface of the display panel DP than the lower surface of the protective film PF is.

The first pattern PT1 may be defined or formed on the lower surface of the protective film PF. In an embodiment, the first pattern PT1 may be formed to overlap the first bending region BA1 of the protective film PF. The first pattern PT1 may be depressed or recessed toward the upper surface of the protective film PF from the lower surface of the protective film PF. In an embodiment, for example, the first pattern PT1 may be a concave pattern formed by removing a portion of the protective film PF using a laser. However, a method of forming the first pattern PT1 is not limited thereto, and alternatively, the first pattern PT1 may be formed through a sputtering process or an energy beam process. A plurality of first patterns PT1 may be provided. In an embodiment, for example, eight first patterns PT1 may be provided.

In an embodiment, the width WD of each of the first patterns PT1 may be constant in the third direction DR3. Alternatively, without being limited thereto, the width WD of each of the first patterns PT1 may vary in the third direction DR3. In an embodiment, for example, the width WD of each of the first patterns PT1 may be decreased as being away from the lower surface of the protective film PF toward the upper surface thereof. That is, the shapes of the first patterns PT1 on the section may vary depending on a process condition and a method in which the first patterns PT1 are formed. In an embodiment, the widths WD of the first patterns PT1 in the first direction DR1 may be equal to one another. Alternatively, without being limited thereto, the widths WD of the first patterns PT1 may differ from one another. In an embodiment, for example, the widths WD of the first patterns PT1 may vary depending on the number of first patterns PT1 and the shapes and positions thereof. The widths WD of the first patterns PT1 may be about 10 micrometers (μm).

The depths DT of the first patterns PT1 may be less than or equal to the thickness TT of the protective film PF. In an embodiment, the depths DT of the first patterns PT1 may be in a range from about 35% to about 50% of the thickness TT of the protective film PF. In an embodiment, for example, the thickness TT of the protective film PF may be about 75 μm, and the depths DT of the first patterns PT1 may be about 35 μm. Accordingly, the first patterns PT1 may not affect the adhesive force or damage of the adhesive layer AL in a process of forming the first patterns PT1 and may overlap the adhesive layer AL on the plane.

The first bending region BA1 may include a first patterned region (or, a patterned region) PA1 in which the first patterns PT1 are defined and an unpatterned (or flat) region NPA in which the first patterns PT1 are not defined. Here, the first patterned region PA1 may be defined as a region defined by areas occupied by the first patterns PT1 and areas therebetween, and the unpatterned region NPA is defined as a remaining region except for the first patterned region PA1. The unpatterned region NPA may include a first unpatterned region NPA1 disposed at one side of the first patterned region PA1 and located between the first patterned region PA1 and the flat region FA and a second unpatterned region NPA2 disposed at an opposite side of the first patterned region PA1 that is opposite to the one side. The one side is a region disposed in the first direction DR1 with respect to the first patterned region PA1, and the opposite side is a region disposed in the direction opposite to the first direction DR1 with respect to the first patterned region PA1. Accordingly, the first unpatterned region NPA1 is a region disposed in the first direction DR1 with respect to the first patterned region PA1, and the second unpatterned region NPA2 is a region disposed in the direction opposite to the first direction DR1 with respect to the first patterned region PA1.

Referring to FIGS. 2, 5, 6A and 6B together, when the display panel DP is attached to the window WM, the display panel DP and the protective film PF may be bent with a predetermined curvature. When the display panel DP is attached to the window WM that includes the first to fourth side transmissive surfaces TA-S1, TA-S2, TA-S3, and TA-S4 as bending portions, a crease, a crack, and compressive strain may be generated in regions corresponding to the corner portions D-C1, D-C2, D-C3, and D-C4 of the display panel DP by the window WM. According to an embodiment of the disclosure, the first patterned region PA1 may have a width in a range from about 60% to about 70% of the width of the first bending region BA1. In such an embodiment, the protective film PF may include the plurality of first patterns PT1 in the first bending region BA1, and the width of the first patterned region PA1 in which the first patterns PT1 are defined or formed may be in a range from about 60% to about 70% of the width of the first bending region BA1. In an embodiment, for example, the first patterned region PA1 may have a width of about 2385 μm. Although not illustrated, the above description is identically applied to the third bending region BA3. Accordingly, when the display panel DP is attached to the window WM, external compressive forces applied to the corner portions D-C1, D-C2, D-C3, and D-C4 of the display panel DP may be decreased, and thus the corner portions D-C1, D-C2, D-C3, and D-C4 of the display panel DP may be effectively prevented from being attached while being wrinkled due to a space limitation in the window WM or may be effectively prevented from being cracked due to stress applied thereto.

The width of the first patterned region PA1 may vary depending on the curvature of the first bending portion BS1 (refer to FIG. 2) without being limited to the range of about 60% to about 70% of the width of the first bending region BA1. In an embodiment, the width of the first patterned region PA1 may be adjusted depending on the first curvature with which the first bending portion BS1 is bent. In an embodiment, for example, as the first curvature is decreased, the width of the first patterned region PA1 may be decreased, and as the first curvature is increased, the width of the first patterned region PA1 may be increased.

According to an embodiment of the disclosure, the second unpatterned region NPA2 may have a width in a range from about 20% to about 30% of the width of the first bending region BA1. As the second unpatterned region NPA2 is formed, the first patterns PT1 may not be formed from an end of the protective film PF that corresponds to the outermost portion of the protective film PF. In an embodiment, for example, the second unpatterned region NPA2 may have a width of about 833 μm. Since the second unpatterned region NPA2 has a width in a range from about 20% to about 30% of the width of the first bending region BA1, the external compressive forces applied to the corner portions D-C1, D-C2, D-C3, and D-C4 of the display panel DP may be decreased when compared to those in a comparative example in which the second unpatterned region NPA2 is not formed.

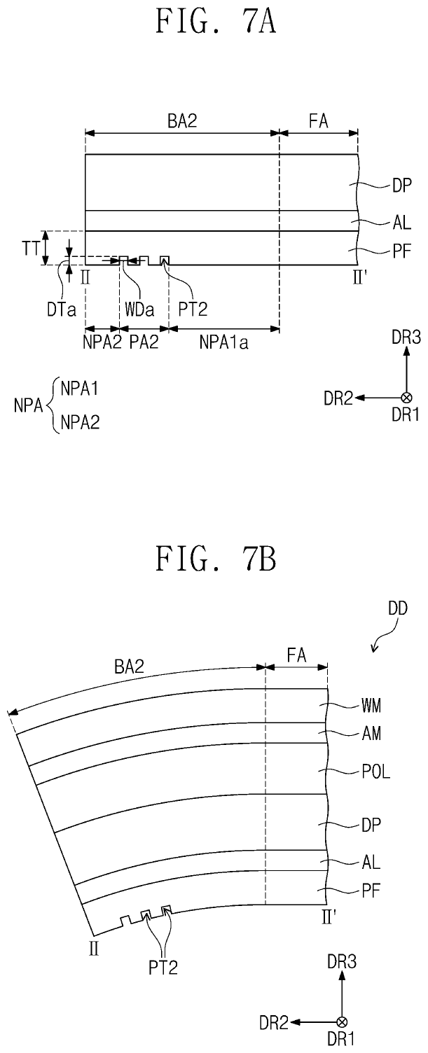

FIG. 7A is a sectional view of the display panel and the protective film illustrating a portion corresponding to line II-II′ of FIG. 5. FIG. 7B is a sectional view of the display device illustrating a shape in which a portion of the display device is bent about a bending axis. Hereinafter, any repetitive detailed descriptions of the same or like elements as those described above will be omitted.

Referring to FIGS. 7A and 7B, the second pattern PT2 may be formed on the lower surface of the protective film PF. Specifically, the second pattern PT2 may be formed to overlap the second bending region BA2 of the protective film PF. The second pattern PT2 may be depressed or recessed toward the upper surface of the protective film PF from the lower surface of the protective film PF. In an embodiment, for example, likewise to the first pattern PT1 (refer to FIG. 6A), the second pattern PT2 may be a concave pattern formed by removing a portion of the protective film PF using a laser. However, a method of forming the second pattern PT2 is not limited thereto, and alternatively, the second pattern PT2 may be formed through a sputtering process or an energy beam process. A plurality of second patterns PT2 may be provided. In an embodiment, for example, three second patterns PT2 may be provided.

In an embodiment, the width WDa of each of the second patterns PT2 may be constant in the third direction DR3. Alternatively, without being limited thereto, the width WDa of each of the second patterns PT2 may vary in the third direction DR3. In an embodiment, for example, the width WDa of each of the second patterns PT2 may be decreased as being away from the lower surface of the protective film PF toward the upper surface thereof. That is, the shapes of the second patterns PT2 on the section may vary depending on a process condition and a method in which the second patterns PT2 are formed. In an embodiment, the widths WDa of the second patterns PT2 in the second direction DR2 may be equal to one another. Alternatively, without being limited thereto, the widths WDa of the second patterns PT2 may differ from one another. In an embodiment, for example, the widths WDa of the second patterns PT2 may vary depending on the number of second patterns PT2 and the shapes and positions thereof. The widths WDa of the second patterns PT2 may be equal to the widths WD (refer to FIG. 6A) of the first patterns PT1. In an embodiment, for example, the widths WDa of the second patterns PT2 may be about 10 μm.

The depths DTa of the second patterns PT2 may be less than or equal to the thickness TT of the protective film PF. In an embodiment, the depths DTa of the second patterns PT2 may be in a range from about 35% to about 50% of the thickness TT of the protective film PF. The depths DTa of the second patterns PT2 may be equal to the depths DT (refer to FIG. 6A) of the first patterns PT1. In an embodiment, for example, the thickness TT of the protective film PF may be about 75 μm, and the depths DTa of the second patterns PT2 may be about 35 μm. Accordingly, the second patterns PT2 may not affect the adhesive force or damage of the adhesive layer AL in a process of forming the second patterns PT2 and may overlap the adhesive layer AL on the plane.

The second bending region BA2 may include a second patterned region PA2 in which the second patterns PT2 are defined and an unpatterned region NPA in which the second patterns PT2 are not defined. The unpatterned region NPA may include a first unpatterned region NP Ala disposed at one side of the second patterned region PA2 and located between the second patterned region PA2 and the flat region FA and a second unpatterned region NPA2 disposed at an opposite side of the second patterned region PA2 that is opposite to the one side. The one side is a region disposed in the direction opposite to the second direction DR2 with respect to the second patterned region PA2, and the opposite side is a region disposed in the second direction DR2 with respect to the second patterned region PA2. Accordingly, the first unpatterned region NPA1a is a region disposed in the direction opposite to the second direction DR2 with respect to the second patterned region PA2, and the second unpatterned region NPA2 is a region disposed in the second direction DR2 with respect to the second patterned region PA2.

The width of the first unpatterned region NPA1a may differ from the width of the first unpatterned region NPA1 illustrated in FIG. 6A. In an embodiment, for example, the width of the first unpatterned region NPA1a may be smaller than the width of the first unpatterned region NPA1 illustrated in FIG. 6A. The width of the second unpatterned region NPA2 may be equal to the width of the second unpatterned region NPA2 illustrated in FIG. 6A. In an embodiment, for example, the second unpatterned region NPA2 may have a width of about 833 μm.

Referring to FIG. 7B, when the display panel DP is attached to the window WM, the display panel DP and the protective film PF may be bent with the second curvature. The display panel DP, the protective film PF, and the window WM illustrated in FIG. 6B are bent with the first curvature, and the display panel DP, the protective film PF, and the window WM illustrated in FIG. 7B are bent with the second curvature less than the first curvature. The number of second patterns PT2 and the width of the second patterned region PA2 may vary depending on the second curvature. In such an embodiment, the number of second patterns PT2 and the width of the second patterned region PA2 may be adjusted depending on the second curvature with which the second bending portion BS2 (refer to FIG. 2) is bent. In an embodiment, for example, as the second curvature is decreased, the number of second patterns PT2 and the width of the second patterned region PA2 may be decreased, and as the second curvature is increased, the number of second patterns PT2 and the width of the second patterned region PA2 may be increased. Accordingly, since the second curvature is less than the first curvature when the embodiments of FIGS. 6B and 7B are compared with each other, the number of second patterns PT2 is smaller than the number of first patterns PT1, and the width of the second patterned region PA2 is smaller than the width of the first patterned region PA1.

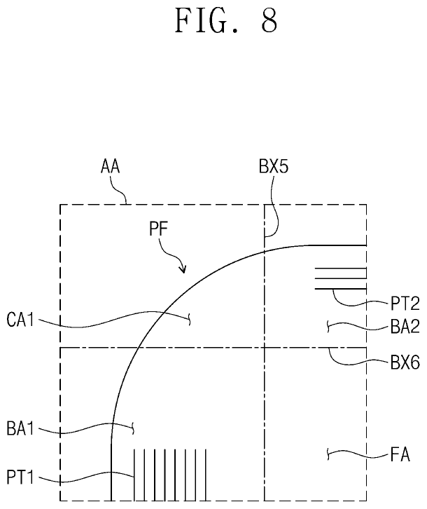

FIG. 8 is an enlarged view of region AA of FIG. 5.

Referring to FIG. 8, in an embodiment, the first corner region CA1 may be disposed between the first bending region BA1 and the second bending region BA2. In such an embodiment, the first corner region CA1 may be connected between the first bending region BA1 and the second bending region BA2 with respect to the fifth bending axis BX5 and the sixth bending axis BX6. The first corner region CA1 may correspond to a corner portion of the protective film PF. The first corner region CA1, the first bending region BA1, and the second bending region BA2 may be connected together to surround the flat region FA.

According to an embodiment of the disclosure, the first patterns PT1 and the second patterns PT2 may not be defined or formed in the first corner region CA1. Accordingly, the first patterns PT1 and the second patterns PT2 may not overlap the first corner portion D-C1 (refer to FIG. 2). Since the first patterns PT1 and the second patterns PT2 are not formed in the first corner region CA1, external compressive forces applied to the corner portions D-C1, D-C2, D-C3, and D-C4 of the display panel DP (refer to FIG. 2) may be decreased when compared to those in a comparative example in which the first patterns PT1 and the second patterns PT2 are formed in the first corner region CA1. Thus, the corner portions D-C1, D-C2, D-C3, and D-C4 of the display panel DP may be effectively prevented from being attached while being wrinkled due to a space limitation in the window WM (refer to FIG. 2) or may be effectively prevented from being cracked due to stress applied thereto.

The description of the first corner region CA1 may be identically applied to the second to fourth corner regions CA2, CA3, and CA4 illustrated in FIG. 5.

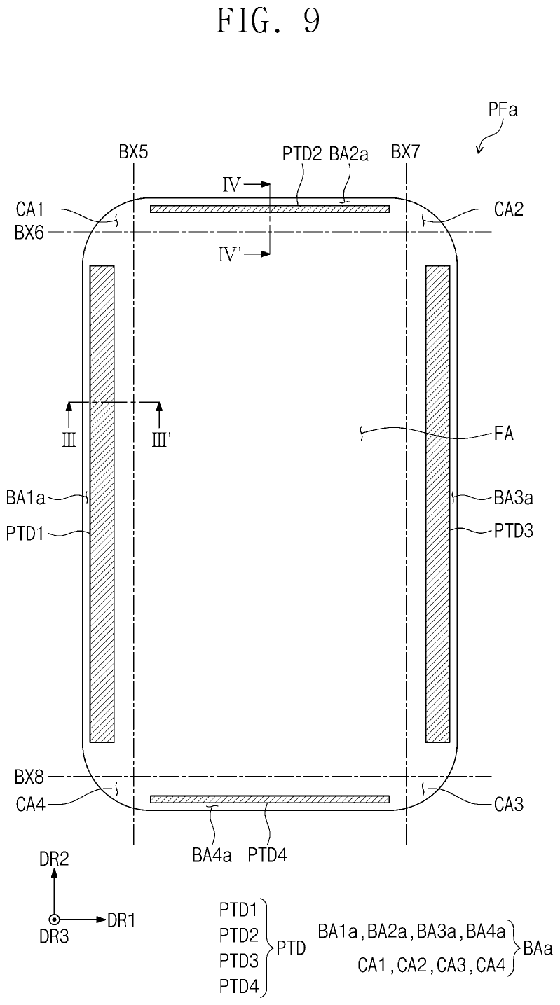

FIG. 9 is a plan view of a protective film according to an alternative embodiment of the disclosure. Hereinafter, any repetitive detailed descriptions of the same or like elements as those described above with reference to FIG. 5 will be omitted or simplified.

Referring to FIG. 9, an embodiment of the protective film PFa may include a bending region BAa and a flat region FA.

In an embodiment, the bending region BAa may include first to fourth bending regions BA1a, BA2a, BA3a, and BA4a and first to fourth corner regions CA1, CA2, CA3, and CA4. In such an embodiment, the first to fourth bending regions BA1a, BA2a, BA3a, and BA4a may correspond to the first to fourth bending portions BS1, BS2, BS3, and BS4 illustrated in FIG. 2. That is, the first bending region BA1a, the second bending region BA2a, the third bending region BA3a, and the fourth bending region BA4a may overlap the first bending portion BS1, the second bending portion BS2, the third bending portion BS3, and the fourth bending portion BS4, respectively.

The first to fourth corner regions CA1, CA2, CA3, and CA4 may correspond to the first to fourth corner portions D-C1, D-C2, D-C3, and D-C4 illustrated in FIG. 2. That is, the first corner region CA1, the second corner region CA2, the third corner region CA3, and the fourth corner region CA4 may overlap the first corner portion D-C1, the second corner portion D-C2, the third corner portion D-C3, and the fourth corner portion D-C4, respectively.

The protective film PFa may include pattern portions PTD. The pattern portions PTD may include a first pattern portion PTD1 defined or formed in the first bending region BA1a, a second pattern portion PTD2 defined or formed in the second bending region BA2a, a third pattern portion PTD3 defined or formed in the third bending region BA3a, and a fourth pattern portion PTD4 defined or formed in the fourth bending region BA4a.

The first pattern portion PTD1 and the third pattern portion PTD3 may extend in the second direction DR2. The first pattern portion PTD1 and the third pattern portion PTD3 may be spaced apart from each other in the first direction DR1 with the flat region FA therebetween. The second pattern portion PTD2 and the fourth pattern portion PTD4 may extend in the first direction DR1. The second pattern portion PTD2 and the fourth pattern portion PTD4 may be spaced apart from each other in the second direction DR2 with the flat region FA therebetween.

According to an embodiment of the disclosure, the width of the first pattern portion PTD1 may differ from the width of the second pattern portion PTD2. In such an embodiment, the width of the first pattern portion PTD1 in the first direction DR1 may differ from the width of the second pattern portion PTD2 in the second direction DR2. In an embodiment, for example, the width of the first pattern portion PTD1 may be greater than the width of the second pattern portion PTD2. The width of the third pattern portion PTD3 may differ from the width of the fourth pattern portion PTD4. In such an embodiment, the width of the third pattern portion PTD3 in the first direction DR1 may differ from the width of the fourth pattern portion PTD4 in the second direction DR2. In an embodiment, for example, the width of the third pattern portion PTD3 may be greater than the width of the fourth pattern portion PTD4.

The first corner region CA1 may be disposed between the first bending region BA1a and the second bending region BA2a. In such an embodiment, the first corner region CA1 may be connected with the first bending region BA1a and the second bending region BA2a. The second corner region CA2 may be disposed between the second bending region BA2a and the third bending region BA3a. In such an embodiment, the second corner region CA2 may be connected with the second bending region BA2a and the third bending region BA3a. The third corner region CA3 may be disposed between the third bending region BA3a and the fourth bending region BA4a. In such an embodiment, the third corner region CA3 may be connected with the third bending region BA3a and the fourth bending region BA4a. The fourth corner region CA4 may be disposed between the fourth bending region BA4a and the first bending region BA1a. In such an embodiment, the fourth corner region CA4 may be connected with the fourth bending region BA4a and the first bending region BA1a.

The first to fourth corner regions CA1, CA2, CA3, and CA4 may correspond to corner portions of the protective film PFa. The first to fourth corner regions CA1, CA2, CA3, and CA4 and the first to fourth bending regions BA1a, BA2a, BA3a, and BA4a may be connected together to surround the flat region FA.

According to an embodiment of the disclosure, the first pattern portion PTD1, the second pattern portion PTD2, the third pattern portion PTD3, and the fourth pattern portion PTD4 may not be defined or formed in the first to fourth corner regions CA1, CA2, CA3, and CA4. Accordingly, the first pattern portion PTD1, the second pattern portion PTD2, the third pattern portion PTD3, and the fourth pattern portion PTD4 may not overlap the first to fourth corner portions D-C1, D-C2, D-C3, and D-C4 (refer to FIG. 2), respectively.

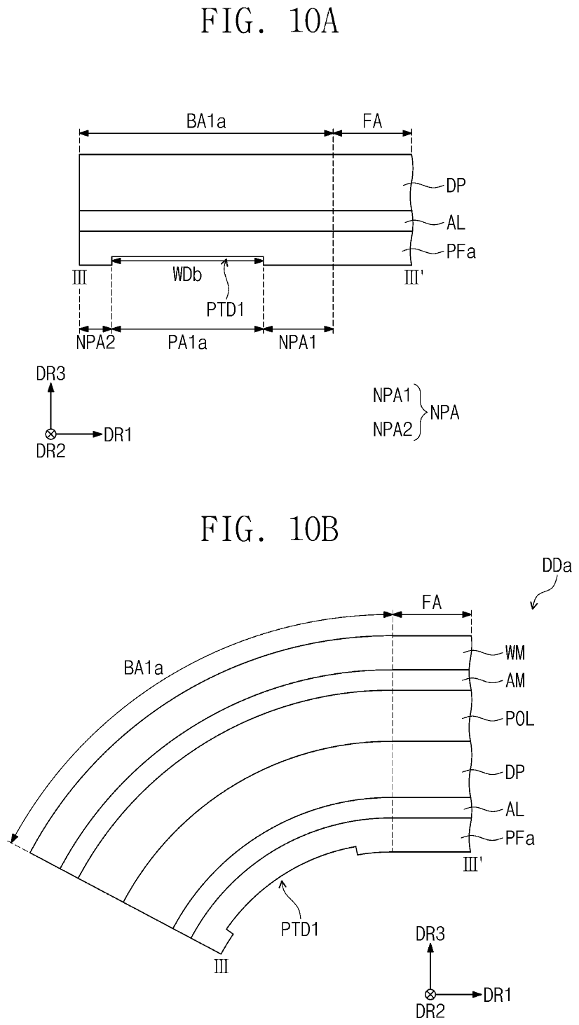

FIG. 10A is a sectional view of a display panel and the protective film illustrating a portion corresponding to line III-III′ of FIG. 9. FIG. 10B is a sectional view of a display device illustrating a shape in which a portion of the display device is bent about a bending axis.

Referring to FIGS. 10A and 10B, an embodiment of the display device DDa may include the display panel DP, an adhesive layer AL, the protective film PFa coupled through the adhesive layer AL disposed at a rear surface of the display panel DP, an adhesive member AM, and a window WM, as described above.

The first pattern portion PTD1 may be defined or formed on a lower surface of the protective film PFa. In an embodiment, the first pattern portion PTD1 may be formed to overlap the first bending region BA1a of the protective film PFa. The first pattern portion PTD1 may be depressed or recessed toward an upper surface of the protective film PFa from the lower surface of the protective film PFa. In an embodiment, for example, the first pattern portion PTD1 may be a concave pattern formed by removing a portion of the protective film PFa using a laser. However, a method of forming the first pattern portion PTD1 is not limited thereto, and alternatively, the first pattern portion PTD1 may be formed through a sputtering process or an energy beam process. According to an embodiment, as shown in FIGS. 10A and 10B, the first pattern portion PTD1 is formed of or defined by a single pattern depressed toward the upper surface of the protective film PFa from the lower surface of the protective film PFa. However, without being limited thereto, the first pattern portion PTD1 may include a plurality of patterns. In an embodiment, for example, the first pattern portion PTD1 may include eight patterns.

In an embodiment, the width WDb of the first pattern portion PTD1 may be constant in the third direction DR3. Alternatively, without being limited thereto, the width WDb of the first pattern portion PTD1 may vary in the third direction DR3. In an embodiment, for example, the width WDb of the first pattern portion PTD1 may be decreased as being away from the lower surface of the protective film PFa toward the upper surface thereof. That is, the shape of the first pattern portion PTD1 on the section may vary depending on a process condition and a method in which the first pattern portion PTD1 is formed. In an embodiment, for example, the width WDb of the first pattern portion PTD1 may be about 2385 μm.

The first bending region BA1a may include a first patterned region (or, a patterned region) PA1a in which the first pattern portion PTD1 is defined and an unpatterned region NPA in which the first pattern portion PTD1 is not defined. The unpatterned region NPA may include a first unpatterned region NPA1 disposed at one side of the first patterned region PA1a and located between the first patterned region PA1a and the flat region FA and a second unpatterned region NPA2 disposed at an opposite side of the first patterned region PA1a that is opposite to the one side. The one side is a region disposed in the first direction DR1 with respect to the first patterned region PA1a, and the opposite side is a region disposed in the direction opposite to the first direction DR1 with respect to the first patterned region PA1a Accordingly, the first unpatterned region NPA1 is a region disposed in the first direction DR1 with respect to the first patterned region PA1a, and the second unpatterned region NPA2 is a region disposed in the direction opposite to the first direction DR1 with respect to the first patterned region PA1a. The width of the first patterned region (or, the patterned region) PA1a may be substantially the same as the width WDb of the first pattern portion PTD1.

Referring to FIGS. 2, 9, 10A and 10B together, when the display panel DP is attached to the window WM, the display panel DP and the protective film PFa may be bent with a predetermined curvature. When the display panel DP is attached to the window WM that includes the first to fourth side transmissive surfaces TA-S1, TA-S2, TA-S3, and TA-S4 as bending portions, a crease, a crack, and compressive strain may be generated in regions corresponding to the corner portions D-C1, D-C2, D-C3, and D-C4 of the display panel DP. According to an embodiment of the disclosure, the first patterned region PA1a may have a width in a range from about 60% to about 70% of the width of the first bending region BA1a. Specifically, the protective film PFa may include the first pattern portion PTD1 in the first bending region BA1a, and the width WDb of the first pattern portion PTD1, that is, the width of the first patterned region PA1a may be in a range from about 60% to about 70% of the width of the first bending region BA1a. In an embodiment, for example, the first patterned region PA1a may have a width of about 2385 μm. Although not illustrated, the above description is identically applied to the third bending region BA3a. Accordingly, when the display panel DP is attached to the window WM, external compressive forces applied to the corner portions D-C1, D-C2, D-C3, and D-C4 of the display panel DP may be decreased, and thus the corner portions D-C1, D-C2, D-C3, and D-C4 of the display panel DP may be effectively prevented from being attached while being wrinkled due to a space limitation in the window WM or may be effectively prevented from being cracked due to stress applied thereto.

In an embodiment, the width WDb of the first pattern portion PTD1 or the width of the first patterned region PA1a may vary depending on the curvature of a first bending portion BS1a. Specifically, the width WDb of the first pattern portion PTD1 or the width of the first patterned region PA1a may be adjusted depending on a first curvature with which the first bending portion BS1a is bent. In an embodiment, for example, as the first curvature is decreased, the width WDb of the first pattern portion PTD1 or the width of the first patterned region PA1a may be decreased, and as the first curvature is increased, the width WDb of the first pattern portion PTD1 or the width of the first patterned region PA1a may be increased.

According to an embodiment of the disclosure, the second unpatterned region NPA2 may have a width in a range from about 20% to about 30% of the width of the first bending region BA1a. As the second unpatterned region NPA2 is formed, the first pattern portion PTD1 may not be formed from an end of the protective film PFa that corresponds to the outermost portion of the protective film PFa. In an embodiment, the second unpatterned region NPA2 may have a width of about 833 μm. Since the second unpatterned region NPA2 has a width in a range from about 20% to about 30% of the width of the first bending region BA1a, the external compressive forces applied to the corner portions D-C1, D-C2, D-C3, and D-C4 of the display panel DP may be decreased when compared to those in a comparative example in which the second unpatterned region NPA2 is not formed.

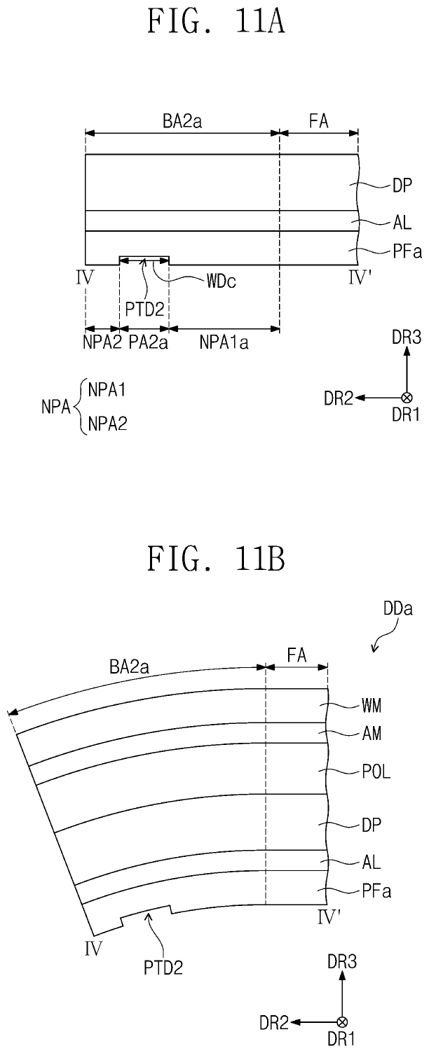

FIG. 11A is a sectional view of the display panel and the protective film illustrating a portion corresponding to line IV-IV′ of FIG. 9. FIG. 11B is a sectional view of the display device illustrating a shape in which a portion of the display device is bent about a bending axis. Hereinafter, any repetitive detailed descriptions of the same or like elements as those described above will be omitted.

Referring to FIGS. 11A and 11B, the second pattern portion PTD2 may be formed on the lower surface of the protective film PFa. Specifically, the second pattern portion PTD2 may be defined to overlap the second bending region BA2a of the protective film PFa. The second pattern portion PTD2 may be depressed or recessed toward the upper surface of the protective film PFa from the lower surface of the protective film PFa. In an embodiment, for example, likewise to the first pattern portion PTD1 (refer to FIG. 10A), the second pattern portion PTD2 may be a concave pattern formed by removing a portion of the protective film PFa using a laser. However, a method of forming the second pattern portion PTD2 is not limited thereto, and alternatively, the second pattern portion PTD2 may be formed through a sputtering process or an energy beam process. According to an embodiment, as shown in FIGS. 11A and 11B, the second pattern portion PTD2 is formed of or defined by a single pattern depressed toward the upper surface of the protective film PFa from the lower surface of the protective film PFa. Alternatively, without being limited thereto, the second pattern portion PTD2 may include a plurality of patterns. In an embodiment, for example, the second pattern portion PTD2 may include three patterns.

In an embodiment, the width WDc of the second pattern portion PTD2 may be constant in the third direction DR3. Alternatively, without being limited thereto, the width WDc of the second pattern portion PTD2 may vary in the third direction DR3. In an embodiment, for example, the width WDc of the second pattern portion PTD2 may be decreased as being away from the lower surface of the protective film PFa toward the upper surface thereof. That is, the shape of the second pattern portion PTD2 on the section may vary depending on a process condition and a method in which the second pattern portion PTD2 is formed. In an embodiment, for example, the width WDc of the second pattern portion PTD2 may be about 505 μm.

The second bending region BA2a may include a second patterned region PA2a in which the second pattern portion PTD2 is defined and an unpatterned region NPA in which the second pattern portion PTD2 is not defined. The unpatterned region NPA may include a first unpatterned region NPA1a disposed at one side of the second patterned region PA2a and located between the second patterned region PA2a and the flat region FA and a second unpatterned region NP A2 disposed at an opposite side of the second patterned region PA2a that is opposite to the one side. The one side is a region disposed in the direction opposite to the second direction DR2 with respect to the second patterned region PA2a, and the opposite side is a region disposed in the second direction DR2 with respect to the second patterned region PA2a. Accordingly, the first unpatterned region NPA1a is a region disposed in the direction opposite to the second direction DR2 with respect to the second patterned region PA2a, and the second unpatterned region NPA2 is a region disposed in the second direction DR2 with respect to the second patterned region PA2a. The width of the second patterned region PA2a may be substantially the same as the width WDc of the second pattern portion PTD2. The width of the first unpatterned region NPA1a may differ from the width of the first unpatterned region NPA1 illustrated in FIG. 10A. In an embodiment, for example, the width of the first unpatterned region NPA1a may be smaller than the width of the first unpatterned region NPA1 illustrated in FIG. 10A. The width of the second unpatterned region NPA2 may be equal to the width of the second unpatterned region NPA2 illustrated in FIG. 10A. In an embodiment, for example, the second unpatterned region NPA2 may have a width of about 833 μm.

Referring to FIG. 11B, when the display panel DP is attached to the window WM, the display panel DP and the protective film PFa may be bent with a second curvature. The display panel DP and the protective film PFa illustrated in FIG. 10B are bent with the first curvature, and the display panel DP and the protective film PFa illustrated in FIG. 11B are bent with the second curvature less than the first curvature. The width WDc of the second pattern portion PTD2 or the width of the second patterned region PA2a may vary depending on the second curvature. Specifically, the width WDc of the second pattern portion PTD2 or the width of the second patterned region PA2a may be adjusted depending on the second curvature with which the second bending portion BS2 (refer to FIG. 2) is bent. In an embodiment, for example, as the second curvature is decreased, the width WDc of the second pattern portion PTD2 or the width of the second patterned region PA2a may be decreased, and as the second curvature is increased, the width WDc of the second pattern portion PTD2 or the width of the second patterned region PA2a may be increased. Accordingly, since the second curvature is less than the first curvature when the embodiments of FIGS. 10B and 11B are compared with each other, the width WDc of the second pattern portion PTD or the width of the second patterned region PA2a is smaller than the width WDb of the first pattern portion PTD1 or the width of the first patterned region PA1a.

The display device according to embodiments of the disclosure may include the protective film coupled to the rear surface of the display panel, and the protective film may include the plurality of patterns to correspond to the bending region of the display panel. The protective film may include a different number of patterns depending on the curvature of the bending region, and thus when the display panel is attached to the window including the bending region, the display panel may be effectively prevented from being wrinkled due to a limited space corresponding to the bent corner portions of the window or may be effectively prevented from being damaged due to the concentration of stress on the display panel. Accordingly, the reliable display device may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a flat portion and a bending portion bent from the flat portion; and
a protective film disposed under the display panel to overlap the flat portion and the bending portion,
wherein the bending portion includes:
a first bending portion which extends from a first side of the flat portion and is bent with a first curvature about a first bending axis; and
a second bending portion which extends from a second side of the flat portion and is bent with a second curvature different from the first curvature about a second bending axis,
wherein the protective film includes:
a plurality of first patterns which extends in a direction parallel to the first bending axis in a first region to overlap the first bending portion; and
a plurality of second patterns which extends in a direction parallel to the second bending axis in a second region to overlap the second bending portion, and
wherein a number of the first patterns and a number of the second patterns differs from each other.

2. The display device of claim 1, wherein the first curvature is greater than the second curvature.

3. The display device of claim 2, wherein the first bending axis and the second bending axis cross each other at a right angle,
wherein the first patterns are arranged in the direction parallel to the second bending axis, and
wherein the second patterns are arranged in the direction parallel to the first bending axis.

4. The display device of claim 3, wherein the number of the first patterns is greater than the number of the second patterns.

5. The display device of claim 2, wherein the protective film includes:
a bending region defined to overlap the first bending portion and the second bending portion; and
a flat region defined to overlap the flat portion.

6. The display device of claim 5, wherein the bending region includes:
a patterned region in which the first patterns and the second patterns are defined; and
an unpatterned region in which the first patterns and the second patterns are not defined.

7. The display device of claim 6, wherein the unpatterned region includes:
a first unpatterned region disposed at one side of the patterned region and located between the patterned region and the flat region; and
a second unpatterned region disposed at an opposite side of the patterned region which is opposite to the one side of the patterned region.

8. The display device of claim 7, wherein the second unpatterned region has a width in a range from about 20% to about 30% of a width of the bending region.

9. The display device of claim 1, wherein the bending portion further includes a corner portion connected between the first bending portion and the second bending portion.

10. The display device of claim 9, wherein the first patterns and the second patterns do not overlap the corner portion.

11. The display device of claim 1, further comprising:
a window disposed on the display panel to overlap the flat portion and the bending portion,
wherein the window includes a side surface which overlaps the bending portion and is bent with a predetermined curvature.

12. The display device of claim 1, wherein the bending portion further includes:
a third bending portion which extends from a third side of the flat portion and is bent with a third curvature about a third bending axis parallel to the first bending axis; and
a fourth bending portion which extends from a fourth side of the flat portion and is bent with a fourth curvature about a fourth bending axis parallel to the second bending axis, and
wherein the third curvature is greater than the fourth curvature.

13. The display device of claim 12, wherein the protective film further includes:
a plurality of third patterns which extends in a direction parallel to the third bending axis in a third region to overlap the third bending portion; and
a plurality of fourth patterns which extends in a direction parallel to the fourth bending axis in a fourth region to overlap the fourth bending portion, and
wherein a number of the third patterns is greater than a number of the fourth patterns.

14. A display device comprising:
a display panel including a flat portion and a bending portion bent from the flat portion; and
a protective film disposed under the display panel to overlap the flat portion and the bending portion,
wherein the bending portion includes:
a first bending portion which extends from a first side of the flat portion and is bent with a first curvature about a first bending axis; and
a second bending portion which extends from a second side of the flat portion and is bent with a second curvature less than the first curvature about a second bending axis perpendicular to the first bending axis, wherein the protective film includes:
a first pattern portion which extends in a direction parallel to the first bending axis in a first region to overlap the first bending portion; and
a second pattern portion which extends in a direction parallel to the second bending axis in a second region to overlap the second bending portion, and
wherein a width of the first pattern portion in the direction parallel to the second bending axis is greater than a width of the second pattern portion in the direction parallel to the first bending axis.

15. The display device of claim 14, wherein the protective film includes:
a bending region defined to overlap the first bending portion and the second bending portion; and
a flat region defined to overlap the flat portion.

16. The display device of claim 15, wherein the bending region includes:
a first patterned region in which the first pattern portion is disposed;
a second patterned region in which the second pattern portion is disposed; and
an unpatterned region in which the first pattern portion and the second pattern portion are not disposed.

17. The display device of claim 16, wherein the first patterned region has a width in a range from about 60% to about 70% of a width of the bending region.

18. The display device of claim 16, wherein the unpatterned region includes:
a first unpatterned region disposed at one side of the first patterned region and located between the first patterned region and the flat region; and
a second unpatterned region disposed at an opposite side of the first patterned region which is opposite to the one side of the first patterned region.

19. The display device of claim 18, wherein the first unpatterned region has a width in a range from about 20% to about 30% of a width of the bending region.

20. The display device of claim 14, wherein the first pattern portion includes a plurality of first patterns which extends in the direction parallel to the first bending axis,
wherein the second pattern portion includes a plurality of second patterns which extends in the direction parallel to the second bending axis, and
wherein a number of the first patterns is greater than a number of the second patterns.
